(19) United States
(12) Patent Application Publication
(10) Pub. No.: US 2011/0155993 A1
(43) Pub. Date: Jun. 30, 2011

(54) PHASE CHANGE MEMORY DEVICES AND FABRICATION METHODS THEREOF

(75) Inventor: Wei-Su Chen, Hsinchu City (TW)

(73) Assignee: INDUSTRIAL TECHNOLOGY RESEARCH INSTITUTE, Hsinchu (TW)

(21) Appl. No.: 12/796,638

(22) Filed: Jun. 8, 2010

(30) Foreign Application Priority Data
Dec. 29, 2009 (TW) TW098145479

(51) Int. Cl. H01L 45/00; H01L 21/06

(52) U.S. Cl. 257/4; 438/102; 257/E45.001; 257/E21.068

(57) ABSTRACT

Phase change memory devices and fabrication methods thereof are presented. A phase change memory device includes a substrate structure. A first electrode is disposed on the substrate structure. A hollowed-cone hydrogen silsesquioxane (HSQ) structure is formed on the first electrode. A multi-level cell phase change memory structure is disposed on the hollowed-cone HSQ structure. A second electrode is disposed on the multi-level cell phase change memory structure.

### CROSS REFERENCE TO RELATED APPLICATIONS

This application is based upon and claims the benefit of priority from a prior Taiwanese Patent Application No. 098145479, filed on Dec. 29, 2009, the entire contents of which are incorporated herein by reference.

### TECHNICAL FIELD

The disclosure relates to phase change memory devices, and in particular to, multi-level phase change memory devices with a tip contact structure and fabrication methods thereof.

### BACKGROUND

Phase change memory devices are non-volatile, highly readable, highly programmable, and low driving voltage/current devices, and normally applied in non-volatile memory devices. In order to meet high density integration and low current requirements, conventional design rules for a phase change memory device are to reduce the contact area between the memory cell and the heating electrode; thus reducing operation currents and minimizing dimensions of transistors to achieve high density and high volume memory devices.

Phase change material in a phase change memory device has at least two solid phases, a crystalline state and an amorphous state. Transformation between these two phases can be achieved by changing the temperature of the phase change material. In its crystalline state, the phase change material presents a regular periodic atomic arrangement exhibiting lower resistance; while in amorphous state, a random atomic arrangement is presented with higher resistance. The resistance difference between the crystalline state and the amorphous state can be as high as four orders of magnitudes. Therefore, whether the phase change material is at the crystalline state or the amorphous state can be easily decided by simple electrical measurements. Among various phase change materials, alloys containing Ge, Sb, and Te are widely applied to modern phase change memory devices.

Since phase transformation between different states of the phase change material is reversible, memory status can be distinguished by telling whether a memory bit is in a low resistance state (crystalline state) or in a high resistance state (amorphous state). More specifically, by deciding among different resistances of a crystalline state or an amorphous state, a digital memory status “0” or “1” can be read from or written to a phase change memory cell.

In order to reduce operation current of a phase change memory device, high resistive electrode material is developed to improve heating efficiency. Meanwhile, reset current density for inducing phase transformation for the phase change memory device can also be reduced. A document published in J. Appl. Phys. Vol. 94 (2003) p. 3536, the entirety of which is hereby incorporated by reference, discloses a phase change memory device. By disposing a high resistive heating layer between a phase change material and a conductive layer, heating efficiency can be improved and current for driving phase transformation can be thus reduced.

Furthermore, in order to enhance efficiency of the phase change memory devices, some prior arts, such as U.S. Pat. No. 5,687,112, U.S. Pat. No. 6,150,253, U.S. Pat. No. 6,287,887, U.S. Pat. No. 6,534,368, U.S. Pat. No. 6,800,563, U.S. Pat. No. 7,057,923, U.S. Pat. No. 7,374,174, and U.S. Patent Pubs.: US2005/0127349, US2007/0138595, US2008/0017894, the entirety of which are incorporated herein by reference, disclose gradually shrunk tip structures of phase change memory devices to further reduce contact area between the bottom conductive structure and the phase change memory element. The desired reset current for implementing the phase change process can therefore be minimized. Meanwhile, in some background arts, a stacked multi-level cell (MLC) is adopted in the phase change memory element to store multiple bits in a single stacked memory unit. However, dimensions of the conventional cone shaped structures are mostly beyond the resolution of state of the art lithographic techniques. The contact area between the bottom conductive structure and the phase change memory element cannot be shrunk to obtain better joule heating effect such that the maximum reset current cannot be reduced. Moreover, due to the shape of the cone shaped structure, the alternated structures of the phase change material and the dielectric material are too close to the metal electrode to lose heat focusing effect.

### SUMMARY

According to one embodiment, a phase change memory device comprises: a substrate structure; a first electrode disposed on the substrate structure; a cone shaped structure formed on the substrate structure; a multi-level cell phase change memory structure disposed on the cone shaped structure; and a second electrode disposed on the multi-level cell phase change memory structure.

According to another embodiment, a phase change memory device comprises: a substrate structure; a first electrode disposed on the substrate structure; a cone shaped structure formed on the substrate structure; a multi-level cell phase change memory structure disposed on the cone shaped structure, wherein the multi-level cell phase change memory structure includes a confined phase change structure atop the cone shaped structure and embedded or filled within a multiple repeat alternated structure; and a second electrode disposed on the multi-level cell phase change memory structure.

According to another embodiment, a method for fabricating a phase change memory device comprises: providing a substrate structure; depositing a first electrode on the substrate structure; forming a cone shaped structure on the substrate structure; sequentially depositing a multiple repeat alternating phase change structure on the first electrode and overlying the cone shaped structure, wherein the multiple repeat alternating phase change structure includes a stack of a phase change material layer and a non-phase change material layer; patterning the multiple repeat alternating phase change structure and the first electrode to create a street structure along a first direction, wherein the patterned first electrode serves as a bit line of the phase change memory device; depositing a HSQ dielectric layer overlying the substrate structure of the phase change memory device, then performing an etch back process lowering a surface of the HSQ dielectric layer to below the height of the street structure; depositing a metallic nitride/metal composite layer on the HSQ dielectric layer; and patterning the metallic nitride/metal composite layer along a second direction to create a word line of the phase change memory device.

According to another embodiment, a method for fabricating a phase change memory device comprises: providing a substrate structure; depositing a first electrode on the substrate structure; forming a cone shaped structure on the substrate structure; sequentially depositing a multiple repeat alternating phase change structure on the first electrode and overlying the cone shaped structure, wherein the multiple repeat alternating phase change structure includes a stack of a phase change material layer and a non-phase change material layer; patterning the multiple repeat alternating phase change structure and the first electrode to create a street structure along a first direction, wherein the patterned first electrode serves as a bit line of the phase change memory device; depositing a first HSQ dielectric layer overlying the substrate structure of the phase change memory device, then performing an etch back process lowering a surface of the first HSQ dielectric layer to below the height of the street structure and exposing a tip of the multiple repeat alternating phase change structure; etching the tip of the multiple repeat alternating phase change structure to create a cavity; removing the phase change material layer of the multiple repeat alternating phase change structure forming multiple gaps; depositing a phase change material layer on the first HSQ dielectric layer and filling the cavity; depositing a metal tungsten compound (e.g., TiW) layer on the phase change material layer; depositing a second HSQ dielectric layer overlying the first HSQ dielectric layer; patterning the second HSQ dielectric layer to create an opening, wherein a bottom of the opening exposes the metal tungsten compound (e.g., TiW) layer; depositing a metallic nitride/metal composite layer on the first HSQ dielectric layer, wherein the metallic nitride/metal composite layer electrically connects to the metal tungsten compound (e.g., TiW) layer via the opening; and patterning the metallic nitride/metal composite layer along a second direction to create a word line of the phase change memory device.

According to one embodiment, a method for fabricating a phase change memory device comprises: providing a substrate structure; depositing a first electrode on the substrate structure; forming a cone shaped structure on the substrate structure; sequentially depositing a multiple repeat alternating phase change structure on the first electrode and overlying the cone shaped structure, wherein the multiple repeat alternating phase change structure includes a stack of a phase change material layer and a non-phase change material layer; patterning the multiple repeat alternating phase change structure and the first electrode to create a street structure along a first direction, wherein the patterned first electrode serves as a bit line of the phase change memory device; depositing a first HSQ dielectric layer overlying the substrate structure of the phase change memory device, then performing an etch back process lowering a surface of the first HSQ dielectric layer to below the height of the street structure and exposing a tip of the multiple repeat alternating phase change structure; etching the tip of the multiple repeat alternating phase change structure to create a cavity; depositing a phase change material layer on the first HSQ dielectric layer and filling the cavity; depositing a metal tungsten compound (e.g., TiW) layer on the phase change material layer; depositing a second HSQ dielectric layer overlying the first HSQ dielectric layer; patterning the second HSQ dielectric layer to create an opening, wherein a bottom of the opening exposes the metal tungsten compound (e.g., TiW) layer; depositing a metallic nitride/metal composite layer on the first HSQ dielectric layer, wherein the metallic nitride/metal composite layer electrically connects the metal tungsten compound (e.g., TiW) layer via the opening; and patterning the metallic nitride/metal composite layer along a second direction to create a word line of the phase change memory device.

### BRIEF DESCRIPTION OF THE DRAWINGS

The disclosure can be more fully understood by reading the subsequent detailed description and examples with references made to the accompanying drawings, wherein:

FIGS. 1-9B are cross sections illustrating fabrication steps for a phase change memory device 100a according a first scheme of the disclosure;

FIGS. 10-16B are cross sections illustrating fabrication steps for a phase change memory device 100b according a second scheme of the disclosure; and

FIGS. 17-18B are cross sections illustrating fabrication steps for a phase change memory device 100c according a third scheme of the disclosure.

### DETAILED DESCRIPTION

It is understood that the following disclosure provides many different embodiments, or examples, for implementing different features of various embodiments. Specific examples of components and arrangements are described below to simplify the present disclosure. These are merely examples and are not intended to be limited. In addition, the present disclosure may repeat reference numerals and/or letters in the various examples. This repetition is for the purpose of simplicity and clarity and does not in itself indicate a relationship between the various embodiments and/or configurations discussed. Moreover, the formation of a first feature over or on a second feature in the description that follows may include embodiments in which the first and second features are formed in direct contact or not in direct contact.

Accordingly, some embodiments provide multi-level phase change memory devices with a tip contact structure (e.g., an HSQ-tip) and fabrication methods thereof. In one embodiment, by removing sacrificial layers, multiple gaps can be generated. Specifically, the sacrificial layers are removed by a specific removal method to create gap structures. In another embodiment, the sacrificial layers can be made of phase change materials, or carbon-containing thin film materials.

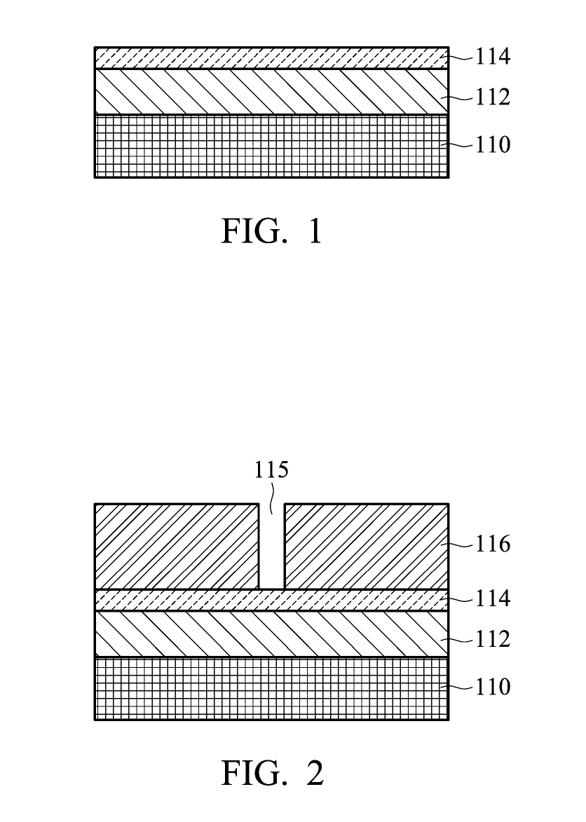

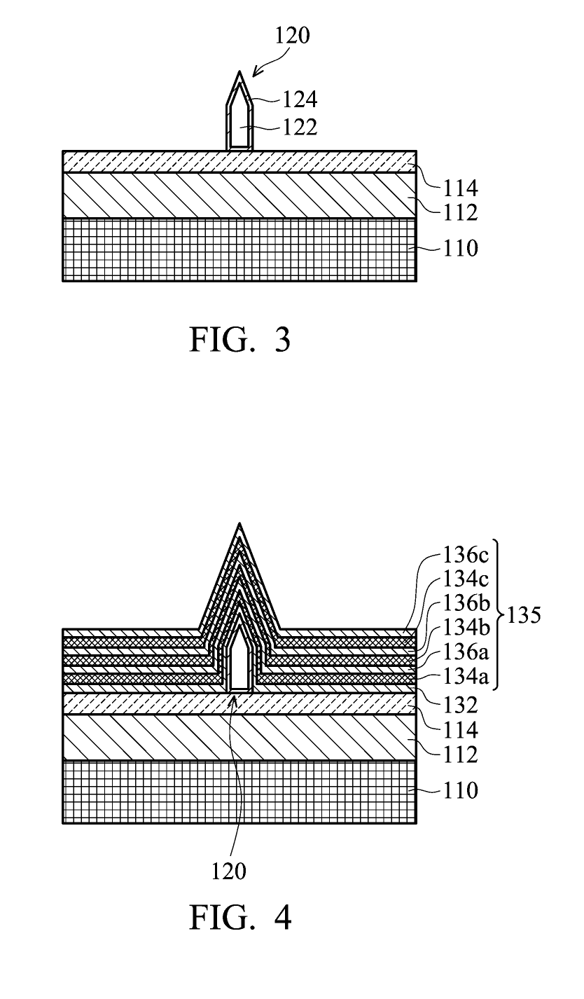

Referring to FIG. 1, a base structure such as a silicon substrate 110 is provided, The silicon substrate 110 includes a thermal oxide layer 112 and a conductive layer 114 (e.g., TiW) formed thereon. Subsequently, a hollow cone shaped structure is formed on the base structure. For example, referring to FIG. 2, a photoresist layer 116 is coated over the conductive layer 114. In one exemplary embodiment, the photoresist layer 116 comprises silicon-free resist materials, such as chain scission resists which can be exposed by electron beam (E-beam) exposure or ion beam exposure, or chemically amplified resist (CAR) which can be exposed by deep ultraviolet (DUV) light or E-beam. Herein, the resist layer 102 can be a ZEP-520A resist (a product of Zeon chemical company) and is not limited thereto. The resist layer 102 is coated with a thickness in a range between about 500 Å and 10000 Å.

Next, an electron beam direct writing process is performed on the photoresist layer 116. After the exposure and development processes, multiple openings 115 are formed in the photoresist layer 116. Each of the opening 16 exposes a part of the underlying conductive layer 114.

Next, a hollow cone shaped structure 120 is formed in the openings 115, and the photoresist layer 116 is then removed. A detailed formation method and fabrication steps are disclosed Taiwan Patent Application No. 97103446 (U.S. patent application Ser. No. 12/205,804), the entire contents of which are incorporated herein by reference, and for simplicity its detailed description is omitted. Referring to FIG. 3, in one embodiment, the hollow cone shaped structure 120 includes a crust structure 124 and a hollowed inner space 122. The crust structure 124 can consist of silicon-containing polymeric materials (such as H(SiO_{3/2})ₙ or hydrogen silsesquioxane (HSQ)) which is characterized as porous low-k dielectric materials. The hollow cone shaped structure 120 consists of a base located on the conductive layer 114 and a gradually shrunk tip.

Referring to FIG. 4, a multi-layered stack structure is formed on the conductive layer 114 and covers the hollow cone shaped structure 120. The multi-layered stack structure includes a conductive layer 132 (e.g., a metal nitride, such as a TaN) and a stack of phase change materials 135. The stack of phase change materials 135 includes at least one alternating phase change memory material and a non-phase change material. In one embodiment, a triple alternated phase change material (e.g, GST) and metallic nitride (e.g., TaN) stacked structure is formed. For example, a periodic repeat triple alternated stack consists of phase change material (e.g, GST) layers 134a-134c and metallic nitride (e.g., TaN) layers 136a-136c. In another embodiment, the conductive layer 132 and the metallic nitride (e.g., TaN) layers 136a-136c are conformal metal layers formed by deposition methods such as sputtering and chemical vapor deposition (CVD). The phase change material (e.g, GST) layers 134a-134c can be phase change materials (e.g., Ge₂Sb₂Te₅) or sacrificial materials.

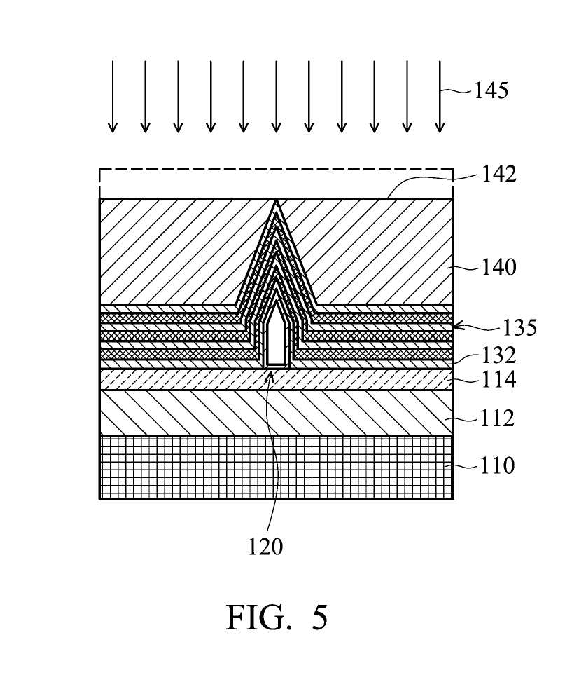

Referring to FIG. 5, a dielectric layer is formed on the multi-layered stack structure. For example, a layer of hydrogen silsesquioxane (HSQ) material 140 (thickness of 3200 Å) is formed on the stack of phase change materials 135 by spin coating. The hydrogen silsesquixane (HSQ) material 140 can be low-k material with excellent flowability and planarization characteristics. Next, an etch back process such as a plasma etching 145 is performed to remove a part of the hydrogen silsesquixane (HSQ) material 140 until the surface 142 exposes a tip of the topmost metallic nitride (e.g., TaN) layer 136 of the stack of phase change materials 135.

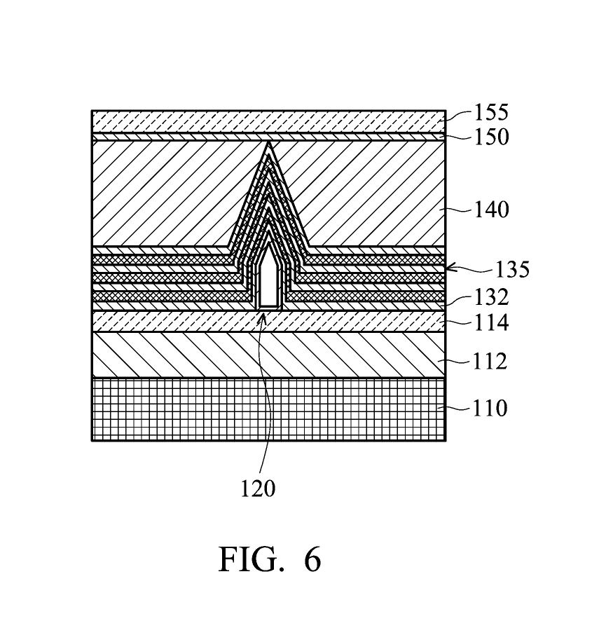

Referring to FIG. 6, a conductive structure is formed on the hydrogen silsesquioxane (HSQ) material 140. For example, a metal nitride (e.g, TaN) layer 150 and a metal tungsten compound (e.g., TiW) layer 155 are deposited on the hydrogen silsesquioxane (HSQ) material 140 by physical vapor deposition (PVD).

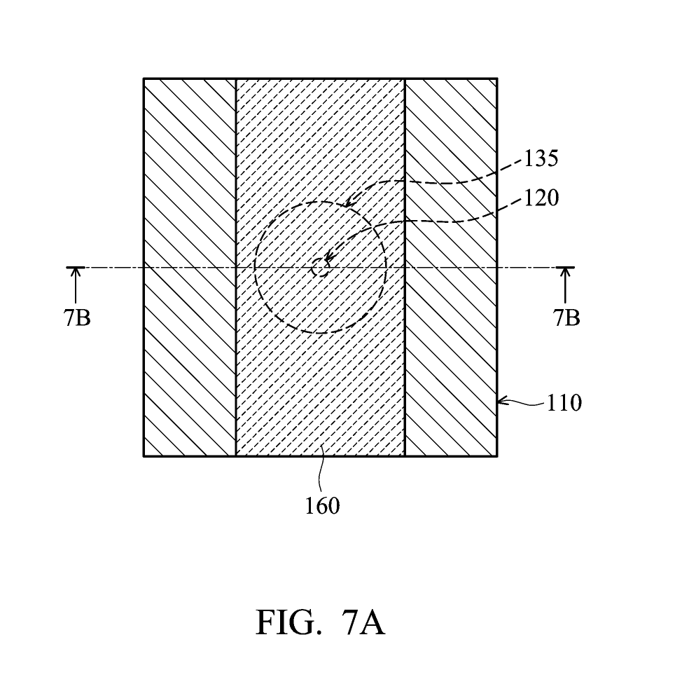

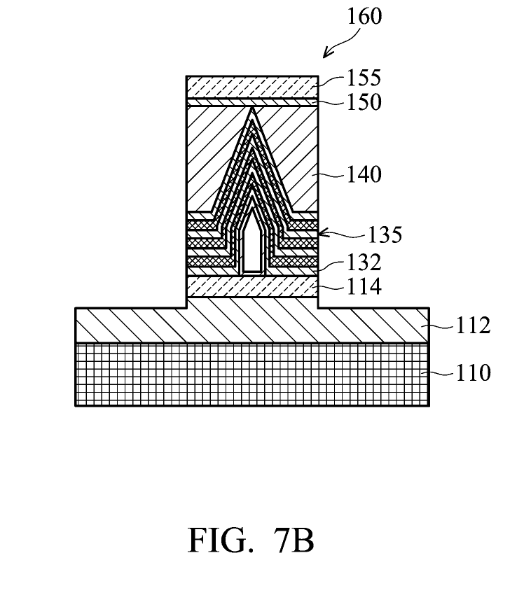

Next, referring to FIG. 7A, optionally or alternatively, an alignment mark is patterned to create a street structure 160 along a first direction (such as X-axis direction), the top view of which is shown in FIG. 7A.

FIG. 7B is a cross section schematically illustrating a street structure along a first direction of a phase change memory device. Next, the conductive layer 114 is patterned along the street structure 160 to serve as a bottom electrode of the phase change memory device. For example, the metal tungsten compound (e.g., TiW) electrode layer 114 is patterned into bit lines of the phase change memory device.

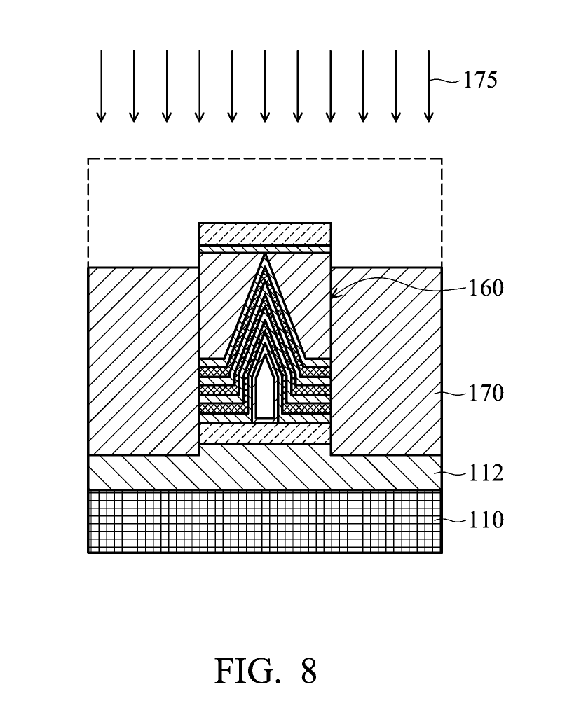

Referring to FIG. 8, a dielectric layer is deposited. For example, an HSQ layer 170 is applied on the phase change memory structure. The entire phase change memory structure can be covered by the HSQ layer 170 due to its flowability and planarization characteristics. Next, an etching back process 175 such as dry plasma etching is performed such that the surface of the HSQ layer 170 is lower than the height of the street structure 160.

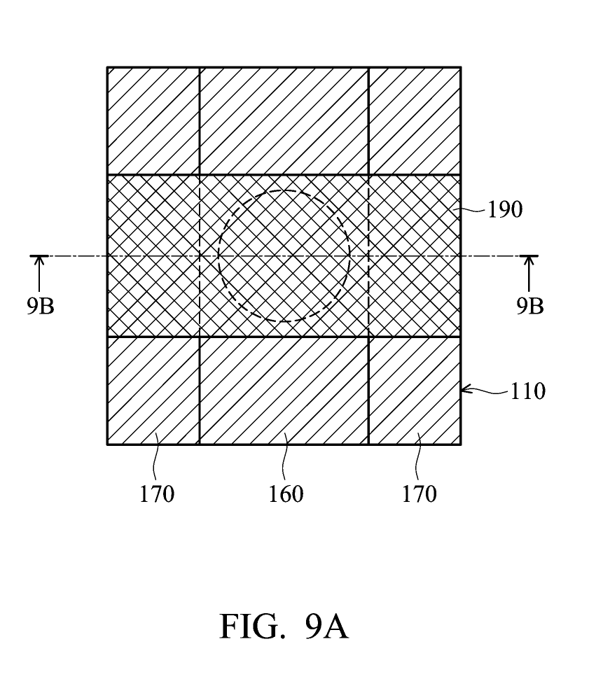

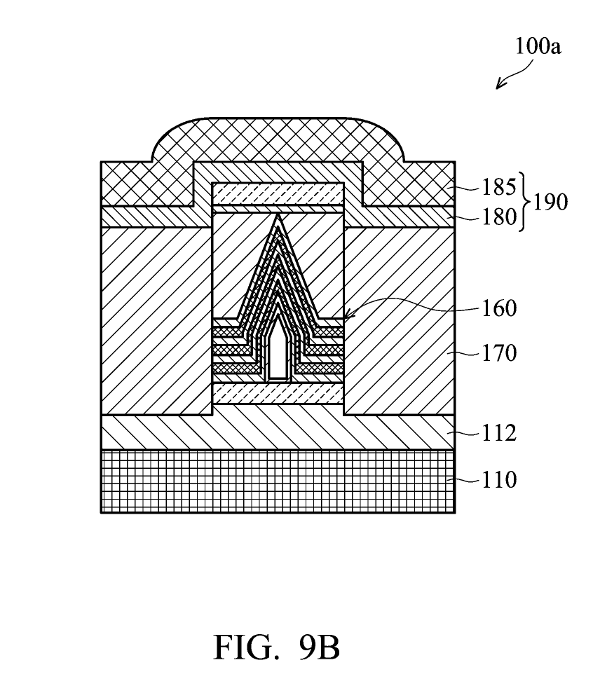

Subsequently, a metal structure 190 including a composite layer of a metal nitride (e.g, TaN) layer 180 and an Al layer 185, overly the HSQ layer 170 to serve as a top electrode of the phase change memory device. The composite layer of metallic nitride/metal (e.g., TaN/Al) 190 is patterned to create a word line along a second direction (such as Y-axis direction), the top view of which is shown in FIG. 9A. FIG. 9B is a cross section schematically illustrating the composite layer of metallic nitride/metal (e.g., TaN/Al) 190 of the phase change memory device.

Accordingly, a first scheme provides a phase change memory device 100a including a substrate structure. The substrate structure includes a semiconductor substrate 110 with a thermal oxide 112 thereon. A first electrode 114 is disposed on the substrate structure. The first electrode 114 includes a metal tungsten compound (e.g., TiW) conductive layer serving as a bit line of the phase change memory device. A cone shaped structure 120 is formed on the substrate structure. A metallic nitride (e.g., TaN) conductive layer 132 is interposed between the cone shaped structure 120 and the multi-level cell phase change memory structure 135, wherein the metallic nitride (e.g., TaN) conductive layer 132 is electrically connected to the first electrode 114. A multi-level cell phase change memory structure 135 is disposed on the cone shaped structure 120, wherein the multi-level cell phase change memory structure 135 includes a triple repeat stack of phase change material (e.g, GST) layers 134a-134c and metallic nitride (e.g., TaN) layers 136a-136c. A second electrode including a metallic nitride (e.g., TaN) layer 150 and a metal tungsten compound (e.g., TiW) layer 155 is disposed on the multi-level cell phase change memory structure 135. A metallic nitride/metal (e.g., TaN/Al) composite layer 190 is electrically connected to the second electrode 150 and 155 and serves as a word line of the phase change memory device. During the etching process of the metallic nitride/metal (e.g., TaN/Al) composite layer 190, the area of the metallic nitride (e.g., TaN) layer 150 and metal tungsten compound (e.g., TiW) layer 155 uncovered by the patterned photoresist is removed.

According to a second scheme, a cavity is formed atop the tip of the cone shaped structure, and a phase change material is filled into the cavity. In an exemplary embodiment, some gaps are formed in the multi-level phase change memory structure by removing a sacrificial layer, thereby enhancing heat concentration effect onto the phase change material.

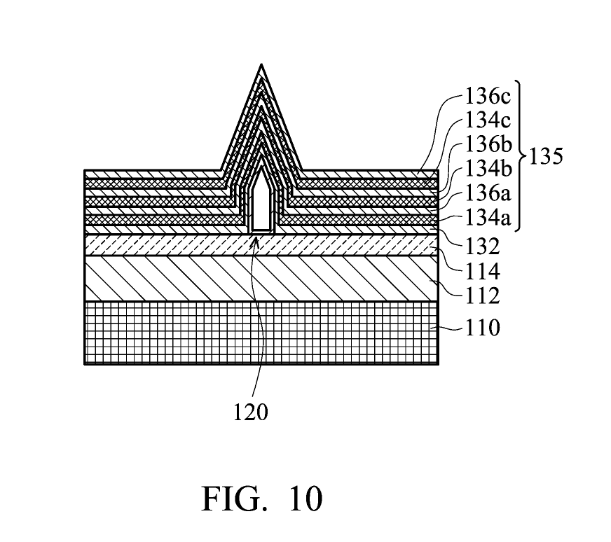

Referring to FIG. 10, the front-end of the fabrication processes for the second scheme is nearly identical to that for the first scheme as shown in FIGS. 1-4, and for simplicity its detailed description is omitted. FIG. 10 illustrates forming of a multi-layer stacked structure 135 over the conductive layer 114 and covering the cone shaped structure 120.

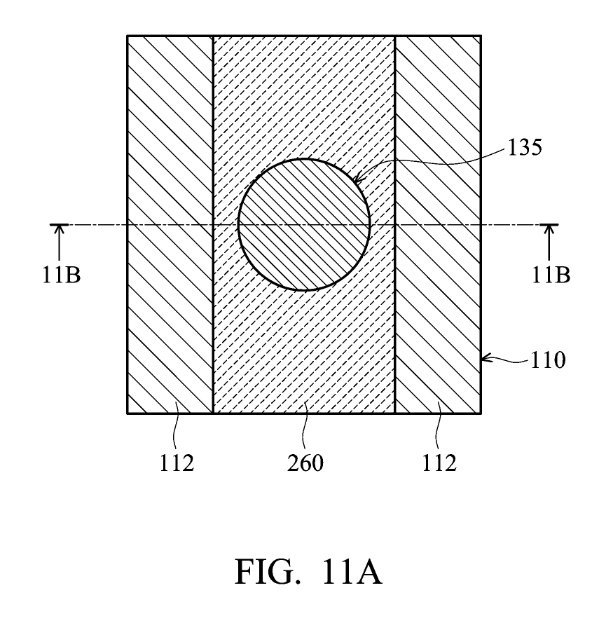

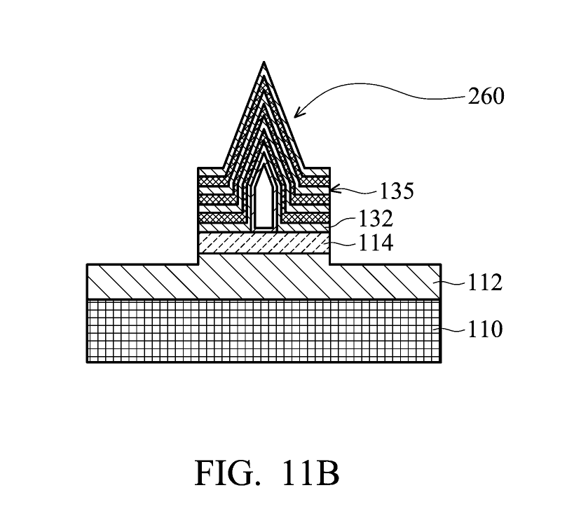

Referring to FIG. 11A, an alignment mark is patterned to create a street structure 260 with stacked layers 135 on the cone shaped structure along a first direction (such as X-axis direction), the top view of which is shown in FIG. 11A. FIG. 11B shows a cross section of creation of the street structure along a first direction of the phase change memory device. Next, the conductive layer 114 is patterned along the street structure 260 to serve as a bottom electrode of the phase change memory device. For example, the metal tungsten compound (e.g., TiW) electrode layer 114 is patterned into bit lines of the phase change memory device.

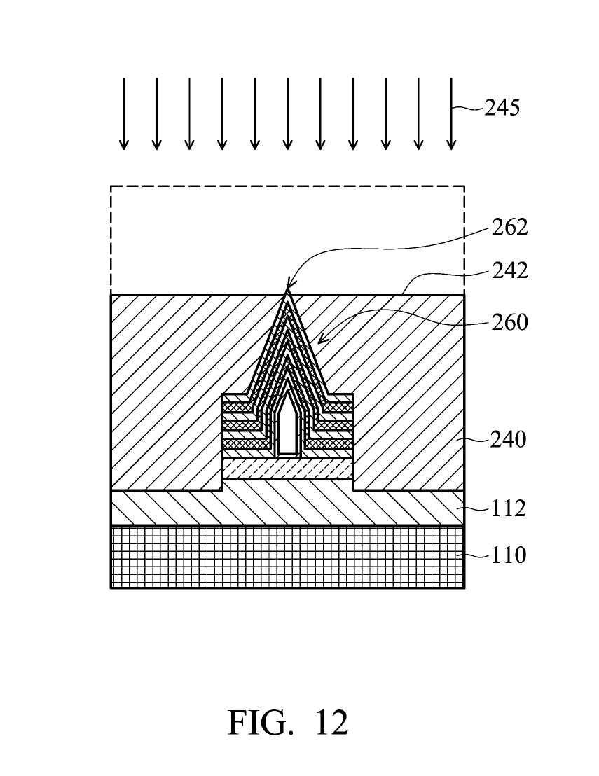

Referring to FIG. 12, a dielectric layer is deposited. For example, an HSQ layer 240 is applied on the phase change memory structure. The entire phase change memory structure can be covered by the HSQ layer due to its flowability and planarization characteristics. Next, an etching back process 245 such as dry plasma etching is performed such that the surface 242 of the HSQ layer 240 is approximately lower than the tip 262 of the street structure 260. That is, etching back of the HSQ layer 240 is precisely controlled to expose a small part of the tip 262 of the street structure 260.

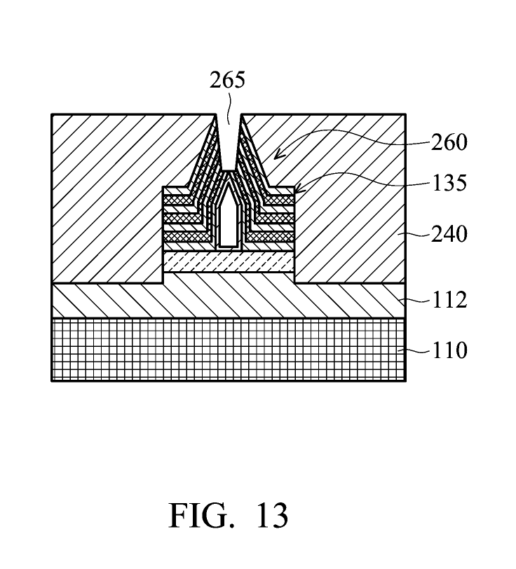

Referring to FIG. 13, the exposed tip 262 is etched through the multiple repeat alternating phase change structure 135 and the conductive layer 132 to create a cavity. The bottom of the cavity exposes the cone shaped structure 120. In this embodiment, the etching process can optionally use chlorine-based plasma etching. The HSQ layer 240 can serve as a self-aligned mask during the etching process. Note that the dielectric layer 240 is not limited to HSQ material, and other low-k dielectric materials with planarization characteristics such as spin-on glass (SOG) can also be used. During the etching process, the triple stack of phase change material (e.g, GST) layers 134a-134c and metallic nitride (e.g., TaN) layers 136a-136c and the conductive layer 132 can be sequentially removed. In another embodiment, the metallic nitride (e.g., TaN) layers 136a-136c can be replaced by other metals or dielectrics (such as Si₃N₄ or SiON).

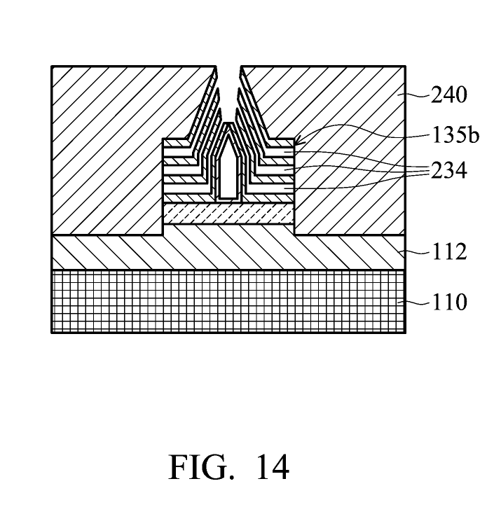

Referring to FIG. 14, a wet etching process is performed to remove the phase change material (e.g, GST) layers 134a-134c leaving gaps 234. A stacked structure 135b consisting of the gaps 234 and metallic nitride (e.g., TaN) layers 136a-136c can thus be formed. In another embodiment, the metallic nitride (e.g., TaN) layers 136a-136c can be replaced by other metals or dielectrics (such as Si₃N₄ or SiON). Accordingly, in one embodiment, the step of removing the phase change material layer comprises removing a part of the phase change material layer using a Gallic Acid clean solution, or a commercial model ACT-970 clean solution. The clean solution can etch phase change materials (e.g, GST) and does not etch metal and dielectric materials. More specifically, the clean solution provides selective etching of the metal, dielectric and phase change materials (e.g, GST). In another embodiment, the step of removing the phase change material layer comprises removing a part of the phase change material layer using H₂-based plasma (e.g, 5% H₂/He plasma). Similarly, though etching the phase change material (e.g, GST), the H₂-based plasma (e.g, 5% H₂/He plasma) does not etch the metal and dielectric materials, i.e., the H₂-based plasma (e.g, 5% H₂/He plasma) etching provides selective etching of the metal, dielectric and phase change materials (e.g, GST).

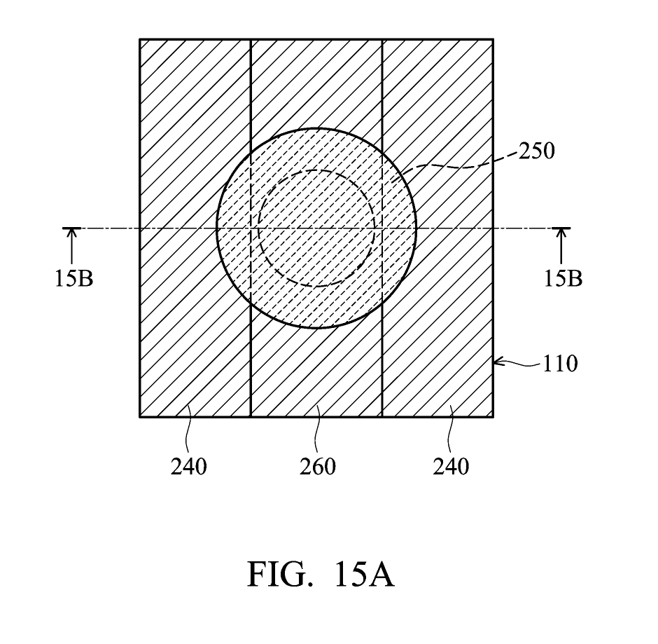

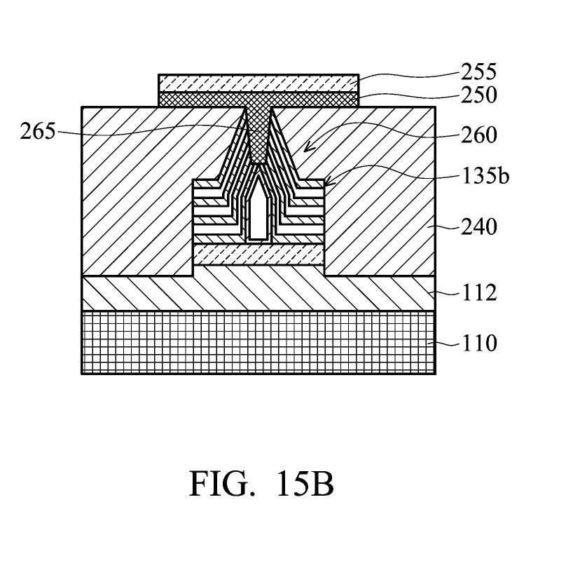

Referring to FIG. 15, a phase change material (e.g, GST) layer 250 is then deposited overlying the dielectric layer 240 and is filled in the cavity. Next, a metal tungsten compound (e.g., TiW) layer 255 is deposited overlying the phase change material (e.g, GST) layer 250. Subsequently, by performing patterning processes, the phase change material (e.g, GST) layer 250 and metal tungsten compound (e.g., TiW) layer 255 are patterned into geometric shapes, such as a circle. FIG. 15B shows a cross section of a patterned phase change material (e.g, GST) layer 250 and metal tungsten compound (e.g., TiW) layer 255 of the phase change memory device. Note that the filled phase change material (e.g, GST) can be confined to a small truncated region, thereby effectively reducing reset current for operating the phase change memory device. Moreover, the step of depositing the phase change material (e.g, GST) layer 250 can optionally use physical vapor deposition (PVD), in which filling capability reaches an aspect ratio (AR) of less than 5. As such, the phase change material (e.g, GST) can only be filled into the cavity and be confined in a small truncated region, and not filled into the stacked structure 135b consisting of alternating gaps 234 and metallic nitride (e.g., TaN) layers 136a-136c.

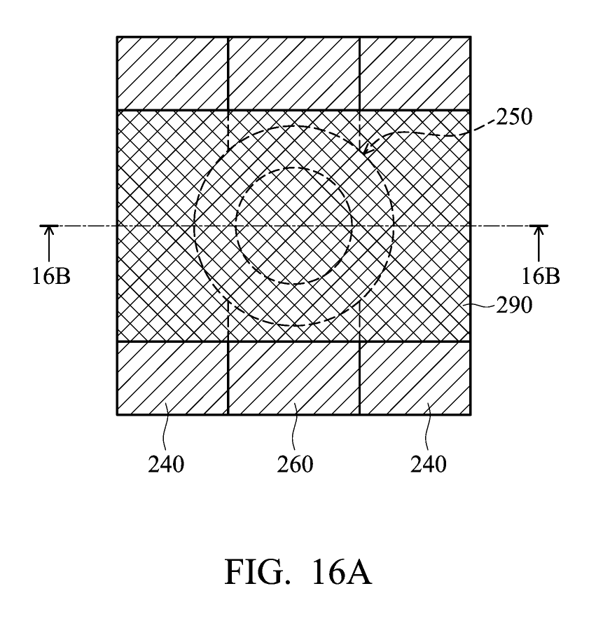

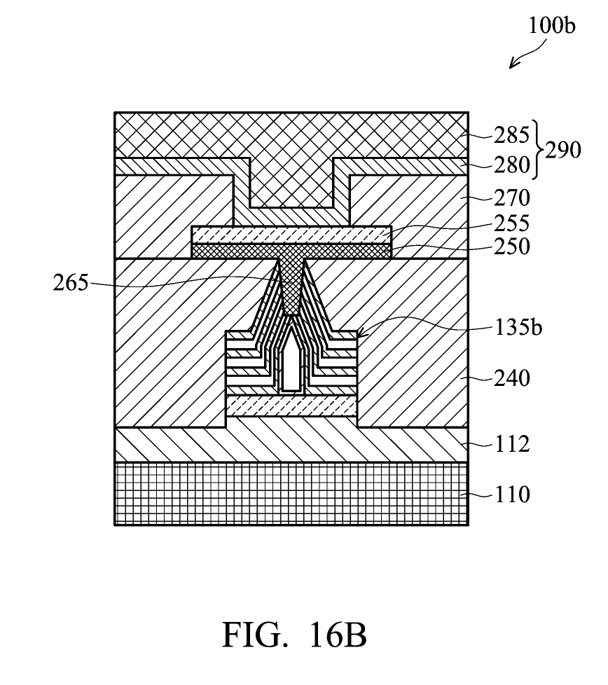

Referring to FIGS. 16A and 16B, a dielectric layer 270 is formed overlying the phase change memory structure. For example, a dielectric layer 270 (such as an HSQ material layer, an SOG material layer, a silicon oxide layer, or a silicon nitride layer) is deposited on the dielectric layer 240 and covers the patterned phase change material (e.g, GST) layer 250 and metal tungsten compound (e.g., TiW) layer 255. Next, an opening is formed exposing the metal tungsten compound (e.g., TiW) layer 255. Next, a metallic nitride (e.g., TaN) layer 280 and an Al layer 285 are conformally formed on the dielectric layer 270 to serve as a top electrode of the phase change memory device. In an embodiment, the metallic nitride (e.g., TaN) layer 280 and Al layer 285 compose a composite layer 290. The composite layer of metallic nitride/metal (e.g., TaN/Al) composite layer 290 is patterned to create a word line along a second direction (such as Y-axis direction), the top view of which is shown in FIG. 16A. FIG. 16B is a cross section schematically illustrating the composite layer of metallic nitride/metal (e.g., TaN/Al) composite layer 290 of the phase change memory device.

Accordingly, a second scheme provides a phase change memory device 100b including a substrate structure. The substrate structure includes a semiconductor substrate 110 with a thermal oxide 112 thereon. A first electrode 114 is disposed on the substrate structure. The first electrode 114 includes a metal tungsten compound (e.g., TiW) conductive layer serving as a bit line of the phase change memory device. A cone shaped structure 120 is formed on the substrate structure. A metallic nitride (e.g., TaN) conductive layer 132 is interposed between the cone shaped structure 120 and the multi-level cell phase change memory structure 135b, wherein the metallic nitride (e.g., TaN) conductive layer 132 is electrically connected to the first electrode 114. The multi-level cell phase change memory structure 135b is formed on the cone shaped structure 120, wherein the multi-level cell phase change memory structure 135b includes a triple repeat stack of gaps 234 and dielectric (or metal) layers. A confined phase change material (e.g, GST) structure 265 is disposed atop the cone shaped structure but not filled into the stacked structure 135b. A second electrode including an unconfined phase change material (e.g, GST) layer 250 and a metal tungsten compound (e.g., TiW) layer 255 is disposed on the multi-level cell phase change memory structure 135b. A metallic nitride/metal (e.g., TaN/Al) composite layer 290 is electrically connected to the second electrodes 250 and 255 and serves as a word line of the phase change memory device.

According to a third scheme, a cavity is formed atop the tip of the cone shaped structure, and a phase change material is filled into the cavity. Since the phase change material (e.g, GST) is confined within a small truncate region, heating effect on the phase change material (e.g, GST) is concentrated, thereby effectively reducing the reset current for operating the phase change memory device. In one exemplary embodiment, the phase change material (e.g, GST) stacked layers 134a-134c are retained in the stacked phase change memory structure to improve heat concentration effect on multi-level cell (MLC) of the phase change memory device.

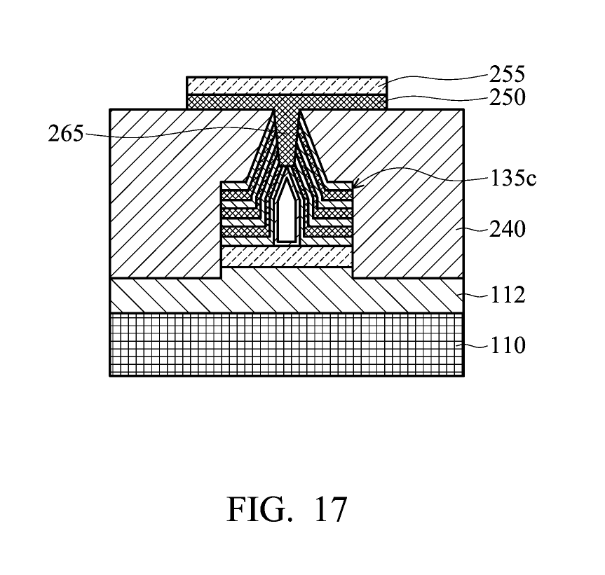

Referring to FIG. 17, the front-end of fabrication processes for the third scheme is nearly identical to that for the first and the second schemes as shown in FIGS. 1-4 and 10-13, and for simplicity its detailed description is omitted. Note that the phase change material (e.g, GST) stacked layers 134a-134c are retained in the present embodiment.

Referring to FIG. 17, a phase change material (e.g, GST) layer 250 is then deposited overlying the dielectric layer 240 and is filled in the cavity. Next, a metal tungsten compound (e.g., TiW) layer 255 is deposited overlying the phase change material (e.g, GST) layer 250. Subsequently, by performing patterning processes, the phase change material (e.g, GST) layer 250 and metal tungsten compound (e.g., TiW) layer 255 are patterned into desired geometric shapes. Note that the filled phase change material (e.g, GST) can be confined within a small truncated region, thereby effectively reducing reset current for operating the phase change memory device. Moreover, the step of depositing the phase change material (e.g, GST) layer 250 can optionally use chemical vapor deposition (CVD), in which filling capability reaches an aspect ratio (AR) of greater than 5. As such, the phase change material (e.g, GST) can easily be filled into the cavity.

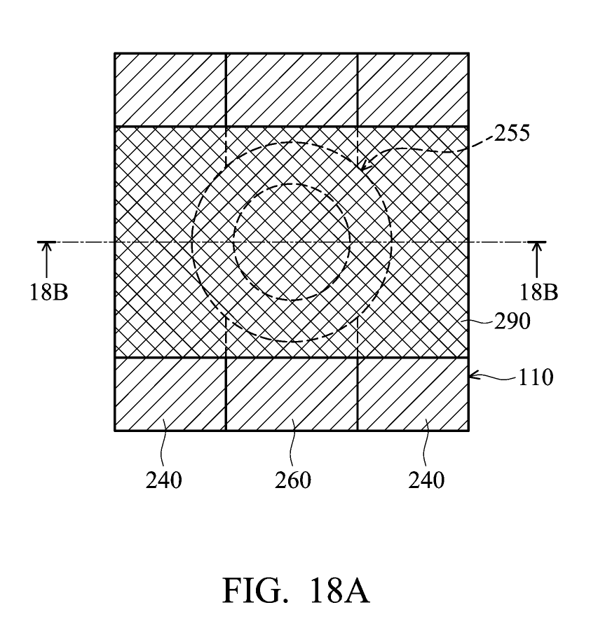

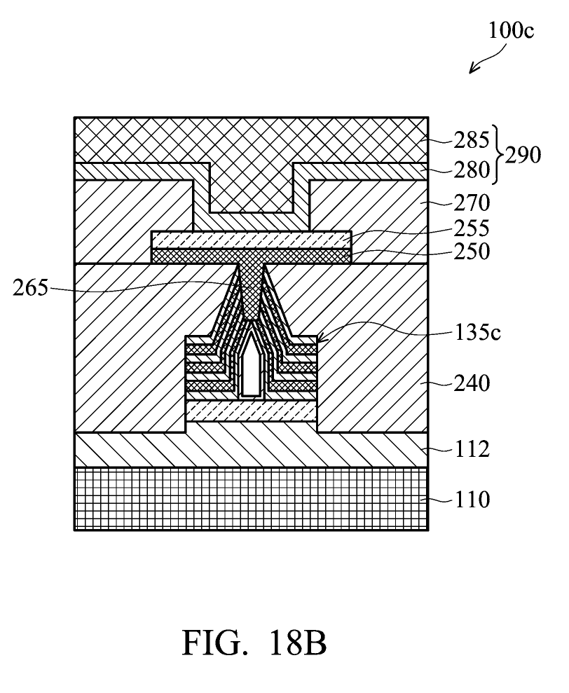

Referring to FIGS. 18A and 18B, a dielectric layer 270 is formed overlying the phase change memory structure. For example, a dielectric layer 270 (such as an HSQ material layer, an SOG material layer, a silicon oxide layer, or a silicon nitride layer) is deposited on the dielectric layer 240 and covers the patterned phase change material (e.g, GST) layer 250 and metal tungsten compound (e.g., TiW) layer 255. Next, an opening is formed exposing the metal tungsten compound (e.g., TiW) layer 255. Next, a metallic nitride (e.g., TaN) layer 280 and an Al layer 285 are conformally formed on the dielectric layer 270 to serve as a top electrode of the phase change memory device. In one embodiment, the metallic nitride (e.g., TaN) layer 280 and Al layer 285 compose a composite layer 290. The composite layer of metallic nitride/metal (e.g., TaN/Al) 290 is patterned to create a word line along a second direction (such as Y-axis direction), the top view of which is shown in FIG. 18A. FIG. 18B is a cross section schematically illustrating the composite layer of metallic nitride/metal (e.g., TaN/Al) 290 of the phase change memory device.

Accordingly, the third scheme provides a phase change memory device 100c including a substrate structure. The substrate structure includes a semiconductor substrate 110 with a thermal oxide 112 thereon. A first electrode 114 is disposed on the substrate structure. The first electrode 114 includes a metal tungsten compound (e.g., TiW) conductive layer serving as a bit line of the phase change memory device. A cone shaped structure 120 is formed on the substrate structure. A metallic nitride (e.g., TaN) conductive layer 132 is interposed between the cone shaped structure 120 and the multi-level cell phase change memory structure 135c, wherein the metallic nitride (e.g., TaN) conductive layer 132 electrically connects the first electrode 114. The multi-level cell phase change memory structure 135c is formed on the cone shaped structure 120, wherein the multi-level cell phase change memory structure 135c includes a triple stack of alternating phase change material (e.g, GST) layers and dielectric (or metal) layers. A confined phase change material (e.g, GST) structure 265 is disposed atop the cone shaped structure but not filled into the stacked structure 135c. A second electrode including an unconfined phase change material (e.g, GST) layer 250 and a metal tungsten compound (e.g., TiW) layer 255 is disposed on the multi-level cell phase change memory structure 135c. A metallic nitride/metal (e.g., TaN/Al) composite layer 290 is electrically connected to the second electrode 250 and 255 and serves as a word line of the phase change memory device.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded to the broadest interpretation so as to encompass all such modifications and similar arrangements.

What is claimed is:

1. A phase change memory device, comprising:
a substrate structure;
a first electrode disposed on the substrate structure;
a cone shaped structure formed on the substrate structure;
a multi-level cell phase change memory structure disposed on the cone shaped structure; and
a second electrode disposed on the multi-level cell phase change memory structure.

2. The phase change memory device as claimed in claim 1, wherein the substrate structure comprises a semiconductor substrate with a thermal oxide thereon.

3. The phase change memory device as claimed in claim 1, wherein the first electrode comprises a metal tungsten compound conductive layer serving as a bit line of the phase change memory device.

4. The phase change memory device as claimed in claim 1, wherein the cone shaped structure comprises a hollowed structure with a crust made of hydrogen silsesquioxane (HSQ).

5. The phase change memory device as claimed in claim 1, further comprising a metallic nitride conductive layer interposed between the cone shaped structure and the multi-level cell phase change memory structure, wherein the metallic nitride conductive layer electrically connects the first electrode.

6. The phase change memory device as claimed in claim 1, wherein the multi-level cell phase change memory structure comprises a multiple repeat stack of a phase change material layer and a non-phase change material layer.

7. The phase change memory device as claimed in claim 6, wherein the multiple repeat stack of a phase change material layer and a non-phase change material layer is a twice repeat stack of a phase change material layer and a metallic nitride layer.

8. The phase change memory device as claimed in claim 1, wherein the multi-level cell phase change memory structure includes a confined phase change structure atop the cone shaped structure, wherein the phase change structure is mounted within the multi-level cell phase change memory structure.

9. The phase change memory device as claimed in claim 8, wherein the multi-level cell phase change memory structure comprises at least a twice repeat stack of a phase change material layer and a dielectric layer or at least a twice repeat stack of an air gap and a metal layer.

10. The phase change memory device as claimed in claim 8, wherein the multi-level cell phase change memory structure comprises at least a twice repeat stack of a phase change material layer and a dielectric layer or at least a twice repeat stack of a phase change material layer and a metal layer.

11. The phase change memory device as claimed in claim 1, wherein the second electrode comprises a stacked structure of a metallic nitride layer and a metal tungsten compound layer.

12. The phase change memory device as claimed in claim 1, further comprising a metallic nitride/metal composite conductive layer electrically connected to the second electrode and serves as a word line of the phase change memory device.

13. A phase change memory device, comprising:
a substrate structure;
a first electrode disposed on the substrate structure;
a cone shaped structure formed on the substrate structure;
a multi-level cell phase change memory structure disposed on the cone shaped structure, wherein the multi-level cell phase change memory structure includes a confined phase change structure atop the cone shaped structure and embedded or filled within a multiple repeat alternated structure; and
a second electrode disposed on the multi-level cell phase change memory structure.

14. The phase change memory device as claimed in claim 13, wherein the substrate structure comprises a semiconductor substrate with a thermal oxide thereon.

15. The phase change memory device as claimed in claim 13, wherein the first electrode comprises a metal tungsten compound conductive layer serving as a bit line of the phase change memory device.

16. The phase change memory device as claimed in claim 13, wherein the cone shaped structure comprises a hollowed structure with a crust made of hydrogen silsesquioxane (HSQ).

17. The phase change memory device as claimed in claim 13, further comprising a metallic nitride conductive layer interposed between the cone shaped structure and the multi-level cell phase change memory structure, wherein the metallic nitride conductive layer electrically connects the first electrode.

18. The phase change memory device as claimed in claim 13, wherein the multiple repeat alternated structure comprises at least a twice repeat stack of a phase change material layer and a dielectric layer or at least a twice repeat stack of a air gap and a metal layer.

19. The phase change memory device as claimed in claim 13, wherein the multiple repeat alternated structure comprises at least a twice repeat stack of a phase change material layer and a dielectric layer or at least a twice repeat stack of a phase change material layer and a metal layer.

20. The phase change memory device as claimed in claim 13, wherein the second electrode includes a stacked structure of an unconfined phase change material layer and a metallic nitride layer.

21. The phase change memory device as claimed in claim 13, further comprising a metallic nitride/metal composite conductive layer electrically connected to the second electrode and serving as a word line of the phase change memory device.

22. A method for fabricating a phase change memory device, comprising:
providing a substrate structure;
depositing a first electrode on the substrate structure;
forming a cone shaped structure on the substrate structure;
sequentially depositing a multiple repeat alternating phase change structure on the first electrode and overlying the cone shaped structure, wherein the multiple repeat alternating phase change structure includes a stack of a phase change material layer and a non-phase change material layer;
patterning the multiple repeat alternating phase change structure and the first electrode to create a street structure along a first direction, wherein the patterned first electrode serves as a bit line of the phase change memory device;
depositing a HSQ dielectric layer overlying the substrate structure of the phase change memory device, then performing an etch back process lowering a surface of the HSQ dielectric layer to below the height of the street structure;
depositing a metallic nitride/metal composite layer on the HSQ dielectric layer; and
patterning the metallic nitride/metal composite layer along a second direction to create a word line of the phase change memory device.

23. The fabrication method as claimed in claim 22, wherein the substrate structure comprises a semiconductor substrate with a thermal oxide thereon.

24. The fabrication method as claimed in claim 22, wherein the first electrode comprises a metal tungsten compound conductive layer.

25. The fabrication method as claimed in claim 22, wherein the cone shaped structure comprises a hollowed structure with a crust made of hydrogen silsesquioxane (HSQ).

26. The fabrication method as claimed in claim 22, further comprising forming a conductive layer between the cone shaped structure and the multiple repeat alternating phase change structure, wherein the conductive layer electrically connects the first electrode.

27. The fabrication method as claimed in claim 22, wherein the multiple repeat alternating phase change structure includes a multiple repeat stack of a phase change material layer and a metallic nitride layer.

28. A method for fabricating a phase change memory device, comprising:
providing a substrate structure;
depositing a first electrode on the substrate structure;
forming a cone shaped structure on the substrate structure;
sequentially depositing a multiple repeat alternating phase change structure on the first electrode and overlying the cone shaped structure, wherein the multiple repeat alternating phase change structure includes a stack of a phase change material layer and a non-phase change material layer;
patterning the multiple repeat alternating phase change structure and the first electrode to create a street structure along a first direction, wherein the patterned first electrode serves as a bit line of the phase change memory device;
depositing a first HSQ dielectric layer overlying the substrate structure of the phase change memory device, then performing an etch back process lowering a surface of the first HSQ dielectric layer to below the height of the street structure and exposing a tip of the multiple repeat alternating phase change structure;
etching the tip of the multiple repeat alternating phase change structure to create a cavity;
removing the phase change material layer of the multiple repeat alternating phase change structure forming multiple gaps;
depositing a phase change material layer on the first HSQ dielectric layer and filling the cavity;
depositing a metal tungsten compound layer on the phase change material layer;
depositing a second HSQ dielectric layer overlying the first HSQ dielectric layer;
patterning the second HSQ dielectric layer to create an opening, wherein a bottom of the opening exposes the metal tungsten compound layer;
depositing a metallic nitride/metal composite layer on the first HSQ dielectric layer, wherein the metallic nitride/metal composite layer electrically connects to the metal tungsten compound layer via the opening; and
patterning the metallic nitride/metal composite layer along a second direction to create a word line of the phase change memory device.

29. The fabrication method as claimed in claim 28, wherein the substrate structure comprises a semiconductor substrate with a thermal oxide thereon.

30. The fabrication method as claimed in claim 28, wherein the first electrode comprises a metal tungsten compound conductive layer.

31. The fabrication method as claimed in claim 28, wherein the cone shaped structure comprises a hollowed structure with a crust made of hydrogen silsesquioxane (HSQ).

32. The fabrication method as claimed in claim 28, further comprising forming a conductive layer between the cone shaped structure and the multiple repeat alternating phase change structure, wherein the conductive layer electrically connects the first electrode.

33. The fabrication method as claimed in claim 28, wherein the multiple repeat alternating phase change structure includes a multiple repeat stack of a phase change material layer and a metallic nitride layer or a multiple repeat stack of a phase change material layer and a dielectric layer.

34. The fabrication method as claimed in claim 28, wherein the step of removing the phase change material layer comprises removing a part of the phase change material layer using Gallic Acid clean solution.

35. The fabrication method as claimed in claim 28, wherein the step of removing the phase change material layer comprises removing a part of the phase change material layer using H₂-based plasma.

36. A method for fabricating a phase change memory device, comprising:
providing a substrate structure;
depositing a first electrode on the substrate structure;
forming a cone shaped structure on the substrate structure;
sequentially depositing a multiple repeat alternating phase change structure on the first electrode and overlying the cone shaped structure, wherein the multiple repeat alternating phase change structure includes a stack of a phase change material layer and a non-phase change material layer;
patterning the multiple repeat alternating phase change structure and the first electrode to create a street structure along a first direction, wherein the patterned first electrode serves as a bit line of the phase change memory device;
depositing a first HSQ dielectric layer overlying the substrate structure of the phase change memory device, then performing an etch back process lowering a surface of the first HSQ dielectric layer to below the height of the street structure and exposing a tip of the multiple repeat alternating phase change structure;
etching the tip of the multiple repeat alternating phase change structure to create a cavity;
depositing a phase change material layer on the first HSQ dielectric layer and filling the cavity;
depositing a metal tungsten compound layer on the phase change material layer;
depositing a second HSQ dielectric layer overlying the first HSQ dielectric layer;
patterning the second HSQ dielectric layer to create an opening, wherein a bottom of the opening exposes the metal tungsten compound layer;
depositing a metallic nitride/metal composite layer on the first HSQ dielectric layer, wherein the metallic nitride/metal composite layer electrically connects the metal tungsten compound layer via the opening; and
patterning the metallic nitride/metal composite layer along a second direction to create a word line of the phase change memory device.

37. The fabrication method as claimed in claim 36, wherein the substrate structure comprises a semiconductor substrate with a thermal oxide thereon.

38. The fabrication method as claimed in claim 36, wherein the first electrode comprises a metal tungsten compound conductive layer.

39. The fabrication method as claimed in claim 36, wherein the cone shaped structure comprises a hollowed structure with a crust made of hydrogen silsesquioxane (HSQ).

40. The fabrication method as claimed in claim 36, further comprising forming a conductive layer between the cone shaped structure and the multiple repeat alternating phase change structure, wherein the conductive layer electrically connects the first electrode.

41. The fabrication method as claimed in claim 36, wherein the multiple repeat alternating phase change structure includes a multiple repeat stack of a phase change material layer and a metallic nitride layer or a multiple repeat stack of a phase change material layer and a dielectric layer.
